(19) United States
(12) Patent Application Publication
(10) Pub. No.: US 2012/0255616 A1
(43) Pub. Date: Oct. 11, 2012

(54) METAL-OXIDE/CARBON-NANOTUBE COMPOSITE MEMBRANE TO BE USED AS A P-TYPE CONDUCTIVE MEMBRANE FOR AN ORGANIC SOLAR CELL, METHOD FOR PREPARING SAME, AND ORGANIC SOLAR CELL HAVING IMPROVED PHOTOVOLTAIC CONVERSION EFFICIENCY USING SAME

(75) Inventors: Dong Chan Lim, Seoul (KR); Kyu Hwan Lee, Changwon-si (KR); Yong Soo Jeong, Changwon-si (KR); Jae Wook Kang, Changwon-si (KR); Sun Young Park, Changwon-si (KR); Mi Yeong Park, Busan (KR); Yeong-Tae Kim, Jinju-si (KR); Won Hyun Shim, Andong-si (KR); Kang Ho Choi, Busan (KR)

(73) Assignee: KOREA INSTITUTE OF MACHINERY AND MATERIALS, Daejeon (KR)

(21) Appl. No.: 13/518,328

(22) PCT Filed: Dec. 20, 2010
(86) PCT No.: PCT/KR10/09118

§ 371 Date: Jun. 21, 2012

(30) Foreign Application Priority Data
Dec. 24, 2009 (KR) 10-2009-0131075

(51) Int. Cl. H01L 51/44; H01L 51/48; B05D 5/12; B82Y 99/00

(52) U.S. Cl. 136/263; 438/63; 977/948; 257/E21.002

(57) ABSTRACT

The present invention relates to a metal-oxide/carbon-nanotube composite membrane to be used as a P-type conductive membrane for an organic solar cell, to a method for preparing same, and to an organic solar cell having improved photovoltaic conversion efficiency using the same. More particularly, the present invention relates to a metal-oxide/carbon-nanotube composite membrane to be used as a P-type conductive membrane for an organic solar cell, wherein said composite membrane is prepared by dispersing single-walled carbon nanotubes in an organic solvent, adding metal oxides to the mixed solution, dispersing the mixed solution to obtain a composite solution, and depositing the thus-obtained composite solution onto a substrate. The method also relates to a method for preparing a metal-oxide/carbon-nanotube composite membrane to be used as a P-type conductive membrane of an organic solar cell, comprising: a step (step 1) of dispersing single-walled carbon nanotubes in an organic solvent; a step (step 2) of adding metal oxides to the mixed solution prepared in step 1, and dispersing the mixed solution to obtain a composite solution; and a step (step 3) of depositing the thus-obtained composite solution onto a substrate. The present invention also relates to an organic solar cell formed by laminating components in the following order: a substrate, an electrode, a photoactive layer, a P-type conductive membrane, and an electrode. The P-type conductive membrane is a metal-oxide/carbon-nanotube composite membrane which is prepared by dispersing single-walled carbon nanotubes in an organic solvent, adding metal oxides to the mixed solution, dispersing the mixed solution to obtain a composite solution, and depositing the thus-obtained composite solution onto a substrate.

### TECHNICAL FIELD

The present invention relates to a metal-oxide/carbon-nanotube composite membrane to be used as a P-type conductive membrane for an organic solar cell, a method for preparing the same, and an organic solar cell having improved photovoltaic conversion efficiency using the same.

### BACKGROUND ART

Referring to FIG. 1, currently available organic solar cell has a structure that includes a photoactive layer in which electron and hole are generated, and a PCBM or PEDOT:PSS layer in which the generated electrons and holes easily moves toward counter electrode. A so-called ‘conventional OPV (Organic Photo Voltaic) cell’ is constructed in the order of substrate/electrode (ITO)/photoactive layer/electrode (Al).

However, this OPV recently shows the following problems: First, since an organic solar cell is formed layer by layer, different properties and interface properties are appeared between the layers. Therefore, photovoltaic conversion efficiency deteriorates. Second, regarding the PEDOT:PSS layer coated on transparent conductive oxide (TCO), oxidation properties are appeared on interface between the PEDOT:PSS layer and electrode (ITO). Accordingly, electrode properties of ITO are degradated. Third, Al electrode is oxidized easily in air.

Nowadays, many techniques are researched to solve the above-mentioned problems. For example, in order to solve the deterioration of photovoltaic conversion efficiency, a method which mixes single-walled/multi-walled carbon nanotubes having excellent conductivity with a photoactive layer has been developed. However, due to aggregation property of carbon nanotubes, dispersion becomes difficult and due to the extremely long length (several μm) and ductility thereof, the tube is easily permeated into different layers when formed in thin layer. Accordingly, the photovoltaic conversion efficiency deteriorates. Although inversed OPV (See FIG. 2) is also researched to solve the above-mentioned problems, oxidation properties of interface, stability of materials and cost remain as unsolved problems.

Therefore, the inventors of the present invention developed a metal-oxide/carbon-nanotube composite membrane to be used as a P-type conductive membrane for an organic solar cell, a method for preparing the same, and an organic solar cell having improved photovoltaic conversion efficiency using the same.

### DISCLOSURE

### Technical Problem

The present invention aims to provide a metal-oxide/carbon-nanotube composite membrane to be used as a P-type conductive membrane for an organic solar cell.

Also, the present invention aims to provide a method for preparing the metal-oxide/carbon-nanotube composite membrane to be used as a P-type conductive membrane for an organic solar cell.

Furthermore, the present invention aims to provide an organic solar cell which has improved photovoltaic conversion efficiency by using a metal-oxide/carbon-nanotube composite membrane to be used as a P-type conductive membrane for an organic solar cell.

### Technical Solution

In order to achieve the object explained above, the present invention provides metal-oxide/carbon-nanotube composite membrane to be used as a P-type conductive membrane for an organic solar cell, prepared by dispersing single walled carbon nanotubes in an organic solvent, adding and dispersing metal oxides in the mixed solution to obtain a composite solution, and depositing the obtained composite solution onto a substrate.

Also, the present invention provides a method for preparing metal-oxide/carbon-nanotube composite membrane to be used as a P-type conductive membrane for an organic solar cell, including steps of: dispersing single walled carbon nanotube in an organic solvent (Step 1); preparing a composite solution by adding and dispersing metal oxide in the mixed solution prepared in step 1 (Step 2); and depositing the obtained composite solution onto a substrate (Step 3).

Further, regarding the organic solar cell laminated in the order of substrate/electrode/photoactive layer/P-type conductive membrane/electrode, the present invention provides organic solar cell having improved photovoltaic conversion efficiency, wherein the P-type conductive membrane is metal oxide/carbon-nanotube composite membrane which is prepared by dispersing single walled carbon nanotubes in an organic solvent, adding and dispersing metal oxides in the mixed solution to obtain a composite solution, and depositing the obtained composite solution onto a substrate.

### Advantageous Effects

According to the present invention, the metal-oxide/carbon-nanotube composite membrane to be used as a P-type conductive membrane for an organic solar cell improves the movement of the hole generated in the photoactive layer by use of single walled carbon nanotube and thus improves the movement balance and speed of the entire electrons and holes. A method of preparing metal oxide/carbon-nanotube composite membrane according to the present invention can deposit the metal oxide/carbon-nanotube by using simple solution process, instead of vacuum process. Accordingly, an organic solar cell having the metal-oxide/carbon-nanotube composite membrane prepared according to the present invention provides improved photovoltaic conversion efficiency, and thus, the organic solar cell with low manufacturing cost and high efficiency can be provided.

### BRIEF DESCRIPTIONS OF DRAWINGS

FIG. 1 is a mimetic diagram illustrating an example of a conventional organic photovoltaic (OPV) cell;

FIG. 2 is a mimetic diagram illustrating an example of an organic solar cell prepared according to a conventional method in which PEDOT:PSS is used as a hole conducting layer;

FIG. 3 is a mimetic diagram illustrating an example of an organic solar cell prepared according to conventional method in which CuO metal oxide nano-particles are used as a hole conducting layer;

FIG. 4 is a mimetic diagram illustrating an example of an organic solar cell prepared according to the present invention;

FIG. 5 is TEM (transmission electron microscope) images of carbon nanotube/metal-oxide prepared according to the present invention ((a): magnified TEM image (b): a TEM image); and

FIG. 6 is a graph presenting photovoltaic conversion efficiency of an organic solar cell prepared according to the present invention and an organic solar cell prepared according to the conventional invention.

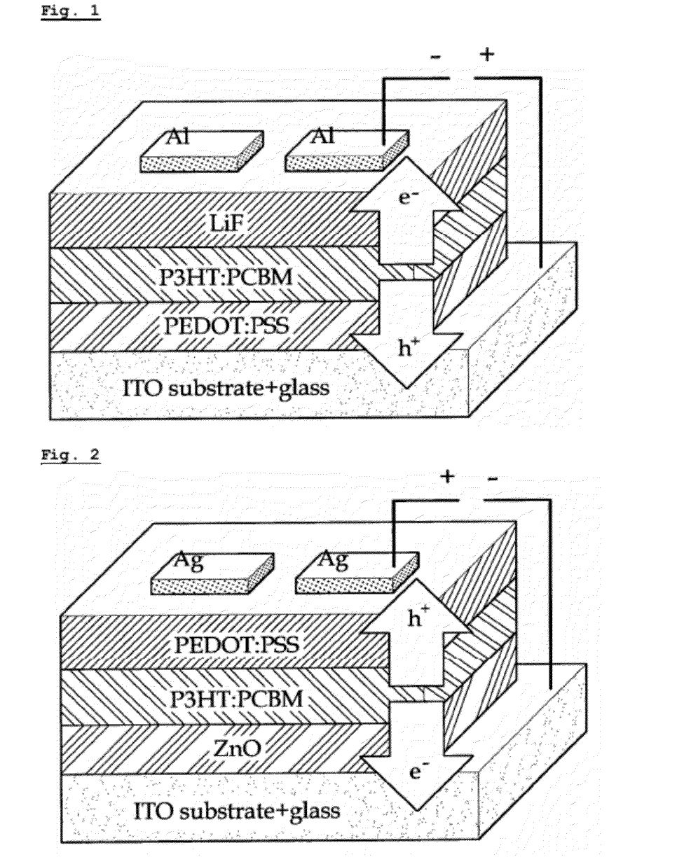

### BEST MODE

The present invention provides metal-oxide/carbon-nanotube composite membrane to be used as a P-type conductive membrane for an organic solar cell, by dispersing single walled carbon nanotube into organic solvent, adding and dispersing metal oxide in the mixed solution to prepare a composite solution, and depositing the obtained composite solution onto a substrate.

Hereinafter, the present invention will be explained in greater detail.

Metal-oxide/carbon-nanotube composite membrane to be used as a P-type conductive membrane for an organic solar cell is prepared by dispersing single walled carbon nanotube into an organic solvent, adding and dispersing metal oxide in the mixed solution to obtain a composite solution, and depositing the obtained composite solution onto a substrate. Average granularity of metal oxide used to form the metal-oxide/carbon-nanotube is preferably between 20-50 nm. Average length of carbon nanotube is preferably between 0.1-1 μm and thickness of metal-oxide/carbon-nanotube composite membrane is preferably between 10-100 nm. If thickness of the metal-oxide/carbon-nanotube composite membrane is under 10 nm, thickness of the membrane becomes too thin, and thus, interface property to the photoactive layer is degradated and the possibility of detaching carbon nanotube from metal-oxide/carbon-nanotube composite membrane is increased. Accordingly, the membrane may not perform required function appropriately. Also, if thickness exceeds 100 nm, the distance for the hole to move increases, and thus, photovoltaic conversion efficiency deteriorates.

In addition, the present invention provides a method of preparing a metal-oxide/carbon-nanotube composite membrane to be used as a P-type conductive membrane for an organic solar cell, including: dispersing single walled carbon nanotube in an organic solvent (Step 1); preparing a composite solution by adding and dispersing metal oxide in the mixed solution prepared in step 1 (Step 2); and depositing the composite solution prepared in step 2 onto a substrate (Step 3).

Each step will be explained in greater detail below.

In the present invention, step 1 is a step of dispersing single walled carbon nonotube into an organic solvent.

The organic solvent of step 1 may include isopropyl alcohol (IPA), dimethylformamide (DMF), or dimethyl sulfoxide (DMSO).

Also, in the present invention, step 2 is a step of preparing a composite solution by adding and dispersing metal oxide in the mixed solution prepared in step 1.

The metal oxide of step 2 may include a P-type metal oxide semiconductor nanoparticle, including copper oxide (CuO), nickel oxide (NiO), tungsten oxide (WO₃), molybdenum oxide (MoO₃), or vanadium oxide (V₂O₅).

Further, in the present invention, step 3 is a step of depositing the composite solution prepared in step 2 onto a substrate.

The deposition of step 3 may be performed by spin coating, spray coating, roll to roll coating (R2R), or dip coating.

In addition, regarding an organic solar cell laminated in the order of substrate/electrode/photoactive layer/P-type conductive membrane/electrode, the present invention provides an organic solar cell improved photovoltaic conversion efficiency, wherein the P-type conductive membrane is a metal oxide/carbon nanotube composite membrane prepared by dispersing single walled carbon nanotube into an organic solvent, preparing a composite solution through addition and dispersion of metal oxide in the mixed solution, and depositing the mixed solution onto a substrate.

Accordingly, the metal-oxide/carbon-nanotube composite membrane to be used as a P-type conductive membrane for an organic solar cell according to the present invention improves the movement of the hole generated in the photoactive layer by use of single walled carbon nanotube and thus improves the movement balance and speed of the entire electrons and holes. A method of preparing metal oxide/carbon-nanotube composite membrane according to the present invention can deposit the metal oxide/carbon-nanotube by using simple solution process, instead of vacuum process. Accordingly, an organic solar cell having the metal-oxide/carbon-nanotube composite membrane prepared according to the present invention provides improved photovoltaic conversion efficiency, and thus, the organic solar cell with low manufacturing cost and high efficiency can be provided.

### MODE FOR CARRYING OUT THE INVENTION

The following is provided to explain the details of the present invention with examples and experimental examples. Wherein, the present invention is only illustrated by the examples, thus, the present invention is not limited as the examples.

### Example 1

### Preparation of Metal-Oxide/Carbon-Nanotube Composite Membrane

Single walled carbon nanotube was placed into isopropanol or dimethylformamide (DMF) and dispersed with ultrasonicator. Copper oxide (CuO) nano-particles were added therein and dispersed with ultrasonicator, and thus, mixed solution was prepared. The temperature of the mixed solution was set to 60° C. The mixed solution was deposited by spin-coating onto a substrate on which a photoactive layer was prepared, and the substrate heated at 150° C., and thus, metal-oxide/carbon-nanotube composite membrane was prepared to be used as a P-type conductive membrane for an organic solar cell.

### Example 2

### Preparation of an Organic Solar Cell Including Metal-Oxide/Carbon-Nanotube Composite Membrane

Transparent conductive oxide (TCO) (i.e., Indium Tin Oxide (ITO)) was deposited onto a substrate (i.e., glass), and ZnO was deposited onto the TCO membrane by electro-chemical method or spin-coating using sol-gel solution. Thickness of ZnO membrane can be regulated by regulating applied voltage, voltage applying time, and concentration ratio of solution for synthesizing ZnO. Poly3-hexylthiophnen (P3HT) and 6,6-phenyl-C61-butyric acid methyl ester (PCBM) were dispersed to dichlorobenzene (DCB) solvent with 1:1 ratio and deposited onto ZnO membrane by spin-coating. Single walled carbon nanotube was dispersed to isopropanol, and copper oxide (CuO) nanoparticles were added and dispersed to prepare a composite solution. The composite solution was deposited onto P3HT:PCBM membrane by spin-coating. Thickness of carbon nanotube-copper oxide composite membrane can be regulated by regulating spinning speed (rpm) of the spin coating equipment. Ag electrode was deposited onto the carbon nanotube-copper oxide composite membrane with vacuum device; therefore, an organic solar cell of the present invention was prepared (See FIG. 4).

### Comparison Example 1

### Preparation of an Organic Solar Cell Including Copper Oxide

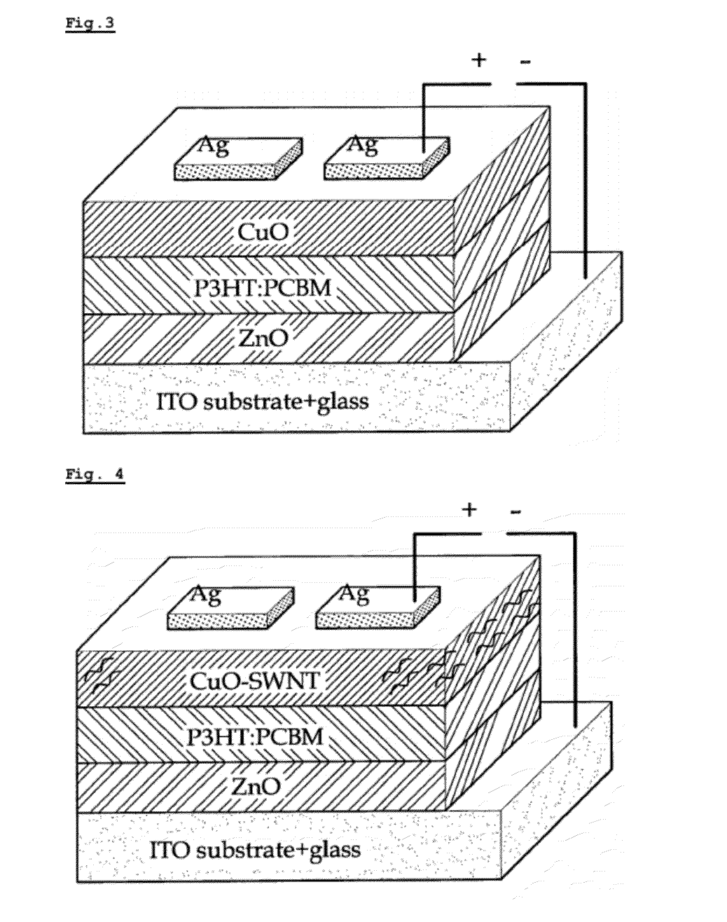

Copper oxide (CuO) nanoparticles were used as a P-type conductive membrane instead of ZnO and an organic solar cell was prepared according to the same steps of the example 2 (See FIG. 3).

### Experiment Example 1

### Analysis of Nano-Structure of Metal Oxide-Carbon Nanotube Composite Membrane

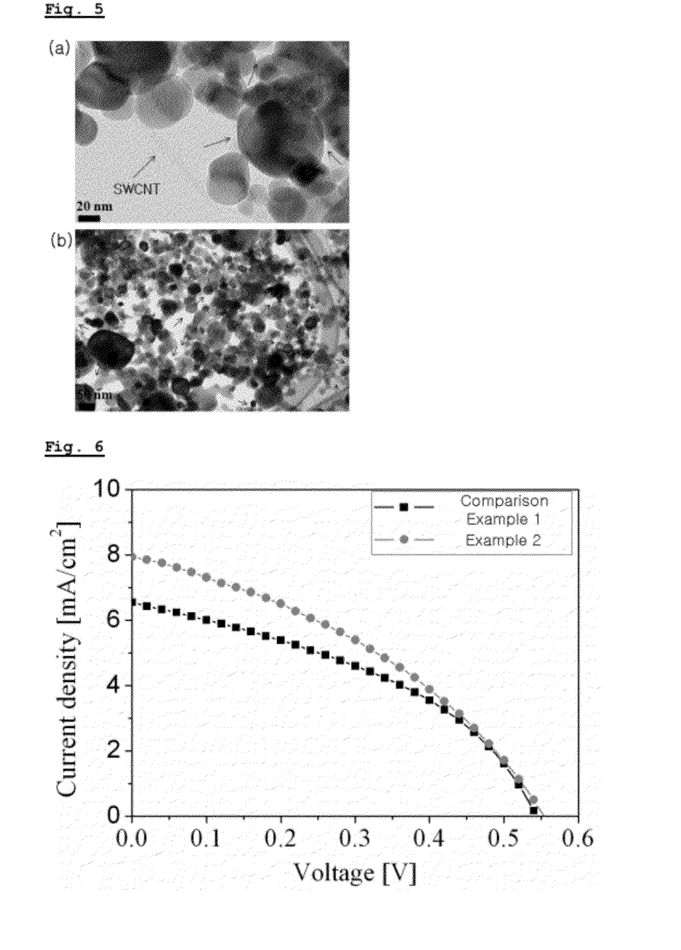

In order to investigate the nano-structure of the metal oxide/carbon nanotube composite membrane prepared according to the present invention, the membrane was analyzed with TEM (JEOL, 2010) and the result is presented in FIG. 5.

Referring to FIG. 5, single walled carbon nanotube (SWCNT) was not tangled, and copper oxide (CuO) nano-particles having below 50 nm of average granularity were evenly dispersed to form a composite membrane.

### Experiment Example 2

### Analysis of Photovoltaic Conversion Efficiency of an Organic Solar Cell

The following experiment was performed in order to measure photovoltaic conversion efficiency for the organic solar cell prepared according to a method of the present invention and the organic solar cell prepared according to the conventional method and the result is presented in FIG. 6 and Table 1.

The photovoltaic conversion efficiency of the organic solar cells was measured with solar simulator. The area of photoactive layer was adjusted to 0.38 cm² with mask, and simulator of the emitted sun-light was measured under the condition of AM 1.5 and 1 sun.

TABLE 1

| | Photovoltaic | | Open- | Short- |
|---|---|---|---|---|
| | conversion | | Circuit | Circuit |
| | efficiency | Fill Factor | Voltage | Current |
| Example | (PCE) | (FF) | (V_{oc}) | (J_{sc}) |
| Example 2 | 1.645 | 0.374 | 0.554 | 7.937 |
| Comparison | 1.447 | 0.407 | 0.543 | 6.546 |
| Example 1 | | | | |

Referring to FIG. 6 and Table 1, it was confirmed that the photovoltaic conversion efficiency of an organic solar cell of the example 2 is about 1.2 times higher than the photovoltaic conversion efficiency of an organic solar cell of the Comparison Example 1. The improvement of photovoltaic conversion efficiency is mainly appeared in short-circuit current (J_{sc}) considering the value of Example 2 and Comparison Example 1 in Table 1. That is, single walled carbon nanotube included in a P-type conductive membrane leads to the improvement of short-circuit current and photovoltaic conversion efficiency. In addition, the photovoltaic conversion efficiency of an organic solar cell can be improved with metal-oxide/carbon-nanotube according to the present invention, by optimizing temperature, heating time and thickness of membrane in process.

1. A metal oxide/carbon nanotube composite membrane to be used as a P-type conductive membrane for an organic solar cell, prepared by dispersing single walled carbon nanotube into an organic solvent, adding and dispersing metal oxide in the mixed solution to obtain a composite solution, and depositing the composite solution onto a substrate.

2. The metal oxide/carbon nanotube composite membrane according to claim 1, wherein average granularity of the metal oxide is between 20-50 nm, length of the carbon nanotube is between 0.1-1 μm and thickness of the metal oxide/carbon nanotube composite membrane is in the range of 10-100 nm.

3. A method for preparing a metal oxide/carbon nanotube composite membrane to be used as a P-type conductive membrane for an organic solar cell, the method comprising:
a step of dispersing single walled carbon nanotube into an organic solvent (Step 1);
a step of preparing a composite solution by adding and dispersing metal oxide in the mixed solution prepared in step 1 (Step 2); and
a step of depositing the composite solution prepared in step 2 onto a substrate.

4. The method according to claim 3, wherein the organic solvent of step 1 is any one selected from the group consisting of: isopropyl alcohol (IPA), dimethylformamide (DMF) and dimethyl sulfoxide (DMSO).

5. The method according to claim 3, wherein the metal oxide of step 2 is a P-type metal oxide semiconductor nanoparticles including copper oxide (CuO), tungsten oxide (WO₃), molybdenum oxide (MoO₃), or vanadium oxide (V₂O₅).

6. The method according to claim 3, wherein the depositing of step 3 comprises spin coating, spray coating, roll to roll coating (R2R), or dip coating.

7. An organic solar cell improved photovoltaic conversion efficiency, which is laminated in the order of a substrate/an electrode/a photoactive layer/a P-type conductive membrane/an electrode, wherein the P-type conductive membrane is prepared by dispersing single walled carbon nanotube into an organic solvent, adding and dispersing metal oxide in the mixed solution to obtain a composite solution, and depositing the composite solution onto a substrate.
